(19) United States
(12) Patent Application Publication
(10) Pub. No.: US 2004/0017130 A1
(43) Pub. Date: Jan. 29, 2004

(54) Adjusting the frequency of film bulk acoustic resonators

(76) Inventors: Li-Peng Wang, Santa Clara, CA (US); Qing Ma, San Jose, CA (US); Quan A. Tran, Fremont, CA (US); Teresa Rini, Saratoga, CA (US); Michael Dibattista, Santa Clara, CA (US)

Correspondence Address: Timothy N. Trop, TROP, PRUNER & HU, P.C., STE 100, 8554 KATY FWY, HOUSTON, TX, 77024-1841, US

(21) Appl. No.: 10/201,796

(22) Filed: Jul. 24, 2002

(51) Int. Cl. H03H 9/17

(52) U.S. Cl. 310/311

(57) ABSTRACT

A material may be patterned and defined on the upper electrode of a film bulk acoustic resonator to provide a mass loading effect that adjusts the frequency of one film bulk acoustic resonator on a wafer relative to other resonators on the same wafer. The applied material that has a high degree of etch selectivity with respect to the material of the upper electrode of the film bulk acoustic resonator.

### BACKGROUND

This invention relates generally to front-end radio frequency filters including film bulk acoustic resonators (FBAR).

Film bulk acoustic resonators have many advantages compared to other techniques such as surface acoustic wave (SAW) devices and ceramic filters, particularly at high frequencies. For example, SAW filters begin to have excessive insertion losses above 2.4 gigahertz and ceramic filters are much larger in size and become increasingly difficult to fabricate at increased frequencies.

A conventional FBAR filter may include two sets of FBARs to achieve the desired filter response. The series FBARs have one frequency and the shunt FBARs have another frequency. The frequency of an FBAR is mainly determined by the thickness of its piezoelectric film which approximately equals the half wavelength of the acoustic wave. The frequencies of the FBARs need to be precisely set to achieve the desired filter response.

For example, for a 2 gigahertz FBAR, the thickness of the piezoelectric film may be approximately 1.8 millimeters. A one percent non-uniformity in piezoelectric film thickness may shift the frequency of the filter by approximately 20 megahertz which is not acceptable if a 60 megahertz pass bandwidth is required.

Generally, post-process trimming may be used to correct the frequency. One technique may involve etching the upper electrode or depositing more metal. Another technique involves adding a heating element. However, both of these approaches are problematic in high volume manufacturing, particularly since they are die-level processes that generally have low throughput. In addition, in-situ measurement may be required during the post-process trimming steps. Therefore, the costs are high and the throughput is relatively low.

Thus, there is a need for better ways to adjust the frequency of FBARs.

### BRIEF DESCRIPTION OF THE DRAWINGS

FIG. 1 is an enlarged cross-sectional view of one embodiment of the present invention;

FIG. 2 is a top plan view of the embodiment shown in FIG. 1; and

FIG. 3 is a flow chart for one embodiment of the present invention.

### DETAILED DESCRIPTION

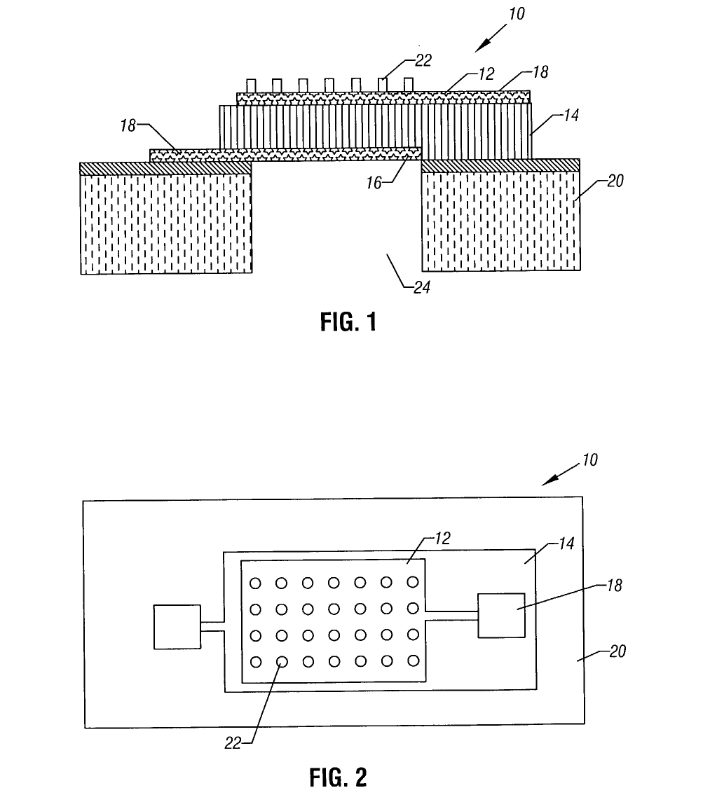

Referring to FIG. 1, a film bulk acoustic resonator (FBAR) 10 may include an upper electrode 12 and a lower electrode 16 sandwiching a piezoelectric layer 14. The entire structure may be supported over a backside cavity 24 in a semiconductor substrate 20. A dielectric film 18 may be interposed between the semiconductor substrate 20 and the remainder of the FBAR 10. As shown in FIGS. 1 and 2, the upper electrode 12 may be coupled to a contact 18 and the bottom electrode 16 may be coupled to a different contact 18.

Over the upper surface of the upper electrode 12 may be distributed a plurality of mass loading dots 22. Each of the dots 22 is on top of the active device area, overlapping the upper and lower electrodes 12 and 22 and the piezoelectric layer 14 as well as the backside cavity 24. The size and spacing of the dots 22 may be smaller than the acoustic wavelength of the FBAR so that the dots 22 do not have any other effect other than mass loading. The material of the dots 22 is advantageously one that has a high etch selectivity with respect to an upper electrode 12. However, the dots may be made of any desired material because just about any material would have the desired mass loading effect.

The dots 22 may be patterned and defined using standard lithography and etching steps as one example. Thus, each of a plurality of FBARs made on a wafer may receive a different number of the dots 22 in order to compensate for slight irregularities in the amount of material utilized for one or more of the components of the FBAR 10.

The frequency compensation may be done by altering the mass loading at the wafer level, achieving relatively high throughput without the need for in-situ measurement in some embodiments. Thus, each FBAR 10 on a wafer may have its frequency adjusted by applying a desired number (or mass) of dots 22 to achieve the originally designed frequency for each particular FBAR 10. By distributing the density of the dots 22 as necessary across a wafer, each FBAR 10 may be individually compensated.

The shape of the dots 22 is subject to considerable variability. While, in some embodiments, it may be desirable to have the dots 22 relatively small compared to the size of the FBAR 10 to enable relatively fine frequency corrections. In other embodiments, a larger single dot 22 may be utilized.

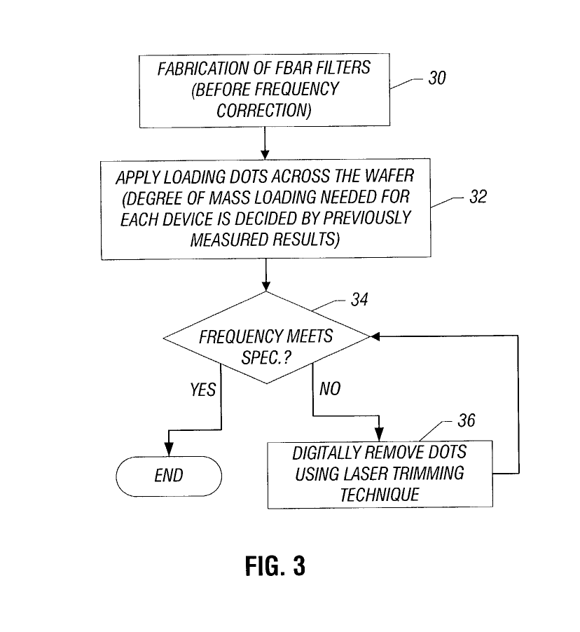

Referring to FIG. 3, the FBAR filters may be fabricated on a wafer as indicated in block 30. Loading dots 22 may be applied across the wafer as indicated in block 32. In one embodiment, the dots 22 may be applied uniformly. The degree of mass loading needed for each filter on the wafer is decided based on previously measured results. Thus, electrical measurements may be done on each FBAR, as fabricated, to determine the necessary frequency correction.

A check at diamond 34 determines whether a given FBAR meets the frequency specification. If so, the flow ends. Otherwise, one or more dots 22 may be digitally removed using a laser trimming technique as indicated in block 36. Thus, in one embodiment of the present invention each of the filters may be given substantially the same loading in terms of the number or mass of dots 22. Thereafter, dots 22 may be removed, using a laser trimming technique to adjust to the desired frequency. In such a technique, the dots 22 may be exposed to a laser beam so that the desired number of dots 22 are vaporized or otherwise removed from the FBAR 10.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
forming a film bulk acoustic resonator on a wafer; and
applying to the resonator on the wafer a mass loading material including a plurality of dots having a size less than the acoustic wavelength of the resonator.

2. The method of claim 1 including forming at least two film bulk acoustic resonators on the same wafer and forming different numbers of dots on each of said resonators.

3. The method of claim 2 including initialing forming the same number of dots on each of said resonators and removing dots from one of said resonators.

4. The method of claim 1 including using patterning techniques to define the dots on said resonator.

5. The method of claim 1 including applying a mass loading material having a high etch selectivity relative to the remainder of said resonator.

6. The method of claim 1 including selectively removing dots from said resonator using a laser.

7. The method of claim 6 including measuring the frequency of said resonator while said resonator is on said wafer and removing dots to adjust the frequency of said resonator.

8. A method comprising:
forming a film bulk acoustic resonator having an upper and lower electrode and a piezoelectric layer between said electrodes; and
applying a material to said upper electrode that is different than the material of said upper electrode to mass load said film bulk acoustic resonator.

9. The method of claim 8 wherein applying the material includes applying a plurality of dots to said upper electrode.

10. The method of claim 9 including applying dots having a size less than the acoustic wavelength of the resonator.

11. The method of claim 10 including applying dots having high etch selectivity with respect to said upper electrode.

12. The method of claim 8 including forming at least two bulk acoustic resonators on the same wafer.

13. The method of claim 12 including applying a plurality of dots having a size smaller than the acoustic wavelength of said resonator to each resonator.

14. The method of claim 13 including removing some of said dots to adjust the mass loading and the frequency of said resonator.

15. The method of claim 14 including removing said dots using a laser.

16. A film bulk acoustic resonator comprising:
a lower electrode;
a piezoelectric layer over said lower electrode;
an upper electrode over said piezoelectric layer; and
a plurality of dots applied to said upper electrode, each of said dots having a size less than the acoustic wavelength of said resonator.
